(19) United States
(12) Patent Application Publication
(10) Pub. No.: US 2022/0319860 A1
(43) Pub. Date: Oct. 6, 2022

(54) ETCHING METHOD AND ETCHING PROCESSING APPARATUS

(71) Applicant: Tokyo Electron Limited, Tokyo (JP)

(72) Inventors: Akira NAKAGAWA, Miyagi (JP); Takumi WATANABE, Miyagi (JP); Akira TANABE, Miyagi (JP); Mizuki MATSUO, Miyagi (JP); Torai IWASA, Miyagi (JP)

(73) Assignee: Tokyo Electron Limited, Tokyo (JP)

(21) Appl. No.: 17/707,316

(22) Filed: Mar. 29, 2022

(30) Foreign Application Priority Data
Mar. 31, 2021 (JP) 2021-061185
Aug. 17, 2021 (JP) 2021-132776

(51) Int. Cl. H01L 21/311; H01L 21/67; H01J 37/32

(52) U.S. Cl. CPC H01L 21/31116; H01L 21/67069; H01J 37/32715; H01J 37/32449; H01J 2237/334

(57) ABSTRACT

An etching method of a substrate includes (a) providing a substrate on a substrate support inside a chamber, the substrate including a first region having a multilayer film in which a silicon oxide film and a silicon nitride film are alternately stacked and a second region having a monolayer silicon oxide film; and (b) etching the substrate with plasma generated from a first processing gas that includes a hydrofluorocarbon gas, wherein the hydrofluorocarbon gas includes a first hydrofluorocarbon gas represented by CxHyFz (x represents an integer of 2 or more, and y and z represent an integer of 1 or more) and having an unsaturated bond.

### CROSS-REFERENCE TO RELATED APPLICATIONS

This application is based on and claims priority from Japanese Patent Application Nos. 2021-061185 and 2021-132776 filed on Mar. 31, 2021 and Aug. 17, 2021, respectively, with the Japan Patent Office, the disclosures of which are incorporated herein in their entireties by reference.

### TECHNICAL FIELD

The present disclosure relates to an etching method and an etching processing apparatus.

### BACKGROUND

Japanese Patent Laid-Open Publication No. 2016-051750 discloses a method of etching a first region having a multilayer film configured by alternately providing a silicon oxide film and a silicon nitride film, and a second region having a monolayer silicon oxide film. According to the etching method described in Japanese Patent Laid-Open Publication No. 2016-051750, a step of generating plasma of a first processing gas that includes a hydrofluorocarbon and a step of generating plasma of a second processing gas that includes a fluorocarbon are alternately and repeatedly performed.

### SUMMARY

One aspect of the present disclosure is an etching method of a substrate, which includes: (a) providing a substrate on a substrate support inside a chamber, the substrate including a first region having a multilayer film in which a silicon oxide film and a silicon nitride film are alternately stacked and a second region having a monolayer silicon oxide film; and (b) etching the substrate with plasma generated from a first processing gas that includes a hydrofluorocarbon gas, wherein the hydrofluorocarbon gas includes a first hydrofluorocarbon gas represented by CxHyFz (x represents an integer of 2 or more, and y and z represent an integer of 1 or more) and having an unsaturated bond.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a vertical sectional view schematically illustrating an example of a configuration of a plasma processing system.

FIGS. 2A and 2B are explanatory views illustrating an example of an etching target layer formed on a surface of a substrate.

FIG. 3 is a flow chart illustrating main steps of a plasma processing according to an embodiment.

FIG. 4 is an explanatory view illustrating an example of a structural formula of a C₃H₂F₄ gas.

FIG. 5 is an explanatory view illustrating an example of an etching process result according to an example.

FIG. 6 is an explanatory view illustrating an example of an etching process result according to an example.

FIG. 7 is an explanatory view illustrating an example of an etching process result according to an example.

FIG. 8 is an explanatory view illustrating an example of an etching process result according to an example.

### DESCRIPTION OF EMBODIMENT

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

In manufacturing processes of a semiconductor device, an etching process is performed using a mask layer on which a pattern is formed as a mask on an etching target layer formed by stacking on a surface of a semiconductor substrate (hereinafter, simply referred to as a “substrate”). This etching process is generally performed in a plasma processing apparatus.

Here, in a recent plasma processing apparatus, as the above-described etching process, a 3D NAND High Aspect Ratio Contact (HARC) step of deeply digging a hole in a substrate formed by stacking the substrate may be performed. In such a 3D NAND HARC step, it is required to form a hole having a high aspect ratio while suppressing a shape abnormality such as bowing.

However, the higher the aspect ratio of the formed hole, the more difficult it becomes to suppress the shape abnormality. In particular, when the etching rate is increased in order to improve the throughput, bowing with respect to a sidewall of the etching hole easily occurs.

The technique according to the present disclosure has been made in consideration of the above-described circumstances, and in the etching process, a shape abnormality such as bowing is suppressed, and an etching shape having a high aspect ratio is appropriately formed. Hereinafter, a plasma processing system according to an embodiment and a plasma processing method that includes an etching method according to the present embodiment will be described with reference to the drawings. The same reference numerals will be given to elements having substantially the same functional configurations throughout the specification and the drawings, and redundant description thereof will be omitted.

<Plasma Processing System>

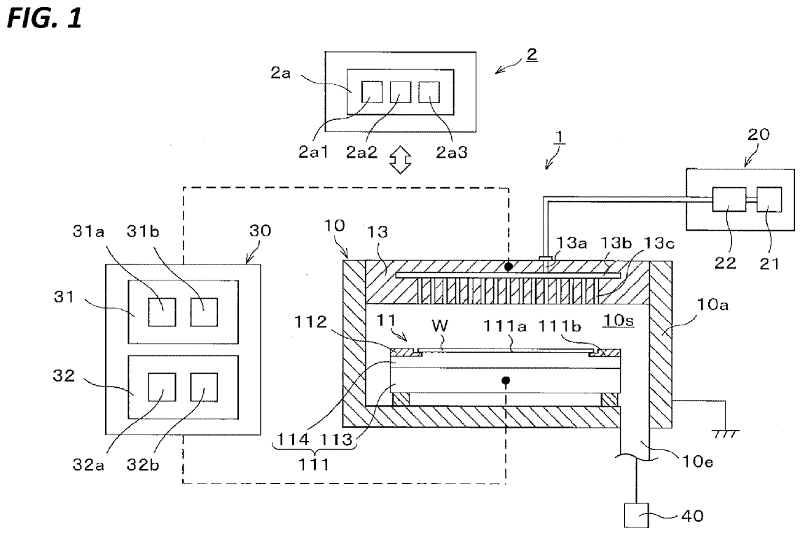

First, a plasma processing system according to an embodiment will be described. FIG. 1 is a vertical sectional view schematically illustrating an outline of a configuration of a plasma processing system.

The plasma processing system includes a capacitively-coupled plasma processing apparatus 1 and a controller 2. A plasma processing apparatus 1 includes a plasma processing chamber 10, a gas supply 20, a power source 30, and an exhaust system 40. Further, the plasma processing apparatus 1 includes a substrate support 11 and a gas introduction unit. The substrate support 11 is disposed inside the plasma processing chamber 10. The gas introduction unit is configured to introduce at least one processing gas into the plasma processing chamber 10. The gas introduction unit includes a shower head 13. The shower head 13 is disposed above the substrate support 11. In one embodiment, the shower head 13 constitutes at least a part of a ceiling of the plasma processing chamber 10. A plasma processing space 10s defined by the shower head 13, a sidewall 10a of the plasma processing chamber 10, and the substrate support 11 is formed inside the plasma processing chamber 10. The plasma processing chamber 10 has at least one gas supply port for supplying at least one processing gas into the plasma processing space 10s, and at least one gas exhaust port for exhausting the gas from the plasma processing space 10s. The sidewall 10a is grounded. The shower head 13 and the substrate support 11 are electrically insulated from the plasma processing chamber 10.

The substrate support 11 includes a main body member 111 and a ring assembly 112. An upper surface of the main body member 111 has a central region 111a (substrate support surface) for supporting a substrate (wafer) W, and an annular region 111b (ring support surface) for supporting the ring assembly 112. The annular region 111b surrounds the central region 111a in a plan view. The ring assembly 112 includes one or a plurality of annular members, and one or at least one of the plurality of annular members is an edge ring.

In one embodiment, the main body member 111 includes a base 113 and an electrostatic chuck 114. The base 113 includes a conductive member. The conductive member of the base 113 functions as a lower electrode. The electrostatic chuck 114 is disposed on an upper surface of the base 113. The upper surface of the electrostatic chuck 114 has the central region 111a and the annular region 111b described above.

Although not illustrated, the substrate support 11 may include a temperature control module configured to adjust at least one of the ring assembly 112, the electrostatic chuck 114, and the substrate W to a target temperature. The temperature control module may include a heater, a heat transfer medium, a flow path, or a combination thereof. A heat transfer fluid, such as brine or gas, flows through the flow path. Further, the substrate support 11 may include a heat transfer gas supply configured to supply a heat transfer gas (backside gas) between a rear surface of the substrate W and an upper surface of the electrostatic chuck 114.

The shower head 13 is configured to introduce at least one processing gas from the gas supply 20 into the plasma processing space 10s. The shower head 13 has at least one gas supply port 13a, at least one gas diffusion chamber 13b, and a plurality of gas introduction ports 13c. The processing gas supplied to the gas supply port 13a passes through the gas diffusion chamber 13b and is introduced into the plasma processing space 10s from the plurality of gas introduction ports 13c. Further, the shower head 13 includes a conductive member. The conductive member of the shower head 13 functions as an upper electrode. The gas introduction unit may include, in addition to the shower head 13, one or more side gas injectors (SGI) that are attached to one or more openings formed in the sidewall 10a.

The gas supply 20 may include at least one gas source 21 and at least one flow rate controller 22. In one embodiment, the gas supply 20 is configured to supply at least one processing gas from the respective corresponding gas sources 21 to the shower head 13 via the respective corresponding flow rate controllers 22. Each flow rate controller 22 may include, for example, a mass flow controller or a pressure-controlled flow rate controller. Further, the gas supply 20 may include one or more flow rate modulation devices that modulate or pulse flow rates of at least one processing gas.

The power source 30 includes an RF power source 31 coupled to plasma processing chamber 10 via at least one impedance matching circuit. The RF power source 31 is configured to supply at least one RF signal (RF power) such as a source RF signal and a bias RF signal to the lower electrode and/or the upper electrode. As a result, plasma is formed from at least one processing gas supplied into the plasma processing space 10s. Accordingly, the RF power source 31 may function as at least a portion of a plasma generator configured to generate plasma from one or more processing gases in the plasma processing chamber 10. Further, by supplying the bias RF signal to the lower electrode, a bias potential can be generated in the substrate W to draw an ionic component in the formed plasma to the substrate W.

In one embodiment, the RF power source 31 includes a first RF generator 31a and a second RF generator 31b. The first RF generator 31a is configured to be coupled to the lower electrode and/or the upper electrode via at least one impedance matching circuit to generate a source RF signal (source RF power) for plasma generation. In one embodiment, the source RF signal has a frequency in the range of 13 MHz to 150 MHz. In one embodiment, the first RF generator 31a may be configured to generate a plurality of source RF signals having different frequencies. The one or the plurality of source RF signals generated are supplied to the lower electrode and/or the upper electrode. The second RF generator 31b is configured to be coupled to the lower electrode via at least one impedance matching circuit to generate the bias RF signal (bias RF power). In one embodiment, the bias RF signal has a lower frequency than the source RF signal. In one embodiment, the bias RF signal has a frequency in the range of 400 kHz to 13.56 MHz. In one embodiment, the second RF generator 31b may be configured to generate a plurality of bias RF signals having different frequencies. The one or the plurality of bias RF signals generated are supplied to the lower electrode. Further, in various embodiments, at least one of the source RF signal and the bias RF signal may be pulsed.

Further, the power source 30 may include a DC power source 32 coupled to the plasma processing chamber 10. The DC power source 32 includes a first DC generator 32a and a second DC generator 32b. In one embodiment, the first DC generator 32a is configured to be connected to the lower electrode and to generate the first DC signal. The generated first bias DC signal is applied to the lower electrode. In one embodiment, the first DC signal may be applied to another electrode, such as an electrode in an electrostatic chuck. In one embodiment, the second DC generator 32b is configured to be connected to the upper electrode to generate a second DC signal. The generated second DC signal is applied to the upper electrode. In various embodiments, at least one of the first and second DC signals may be pulsed. The first and second DC generators 32a and 32b may be provided in addition to the RF power source 31, and the first DC generator 32a may be provided instead of the second RF generator 31b.

The exhaust system 40 may be connected to, for example, a gas exhaust port 10e disposed at a bottom portion of the plasma processing chamber 10. The exhaust system 40 may include a pressure adjusting valve and a vacuum pump. The pressure in the plasma processing space 10s is adjusted by the pressure adjusting valve. The vacuum pump may include a turbo molecular pump, a dry pump, or a combination thereof.

The controller 2 processes computer-executable instructions for instructing the plasma processing apparatus 1 to execute various steps described herein below. The controller 2 may be configured to control the respective components of the plasma processing apparatus 1 to execute the various steps described herein below. In an embodiment, part or all of the controller 2 may be included in the plasma processing apparatus 1. The controller 2 may include, for example, a computer 2a. For example, the computer 2a may include a processor (central processing unit (CPU)) 2a1, a storage 2a2, and a communication interface 2a3. The processor 2a1 may be configured to perform various control operations based on a program stored in the storage 2a2. The storage 2a2 may include a random access memory (RAM), a read only memory (ROM), a hard disk drive (HDD), a solid state drive (SSD), or a combination thereof. The communication interface 2a3 may communicate with the plasma processing apparatus 1 via a communication line such as a local area network (LAN).

While various exemplary embodiments have been described above, various additions, omissions, substitutions and changes may be made without being limited to the exemplary embodiments described above. Indeed, the embodiments described herein may be embodied in a variety of other forms.

For example, the present embodiment has been described by taking a case where the plasma processing system includes the plasma processing apparatus 1 of capacitively-coupled plasma (CCP) as an example. However, the configuration of the plasma processing system is not limited thereto. For example, the plasma processing system may have a processing apparatus that includes a plasma generator for inductively coupled plasma (ICP), electron-cyclotron resonance plasma (ECR plasma), helicon wave excitation plasma (HWP), or surface wave plasma (SWP), for example. Further, a processing apparatus including various types of plasma generators which include an alternating current (AC) plasma generator and a direct current (DC) plasma generator may be used.

<Plasma Processing Method>

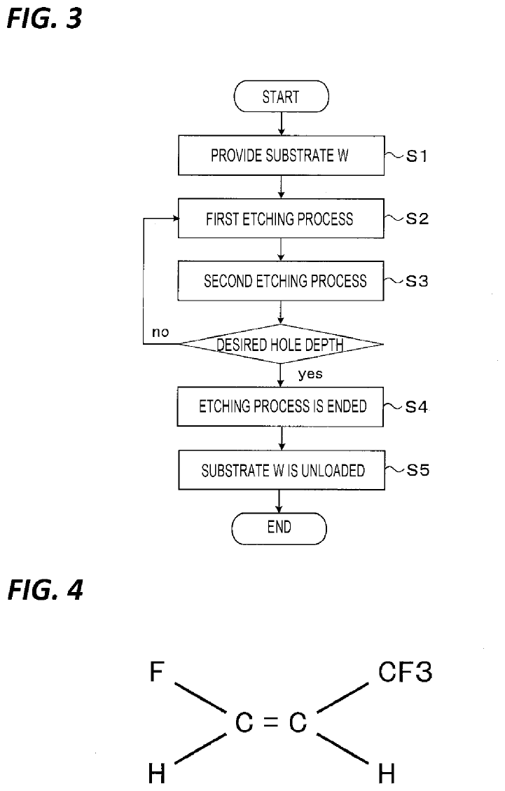

Next, an etching process of the substrate W according to the technique of the present disclosure performed using the plasma processing apparatus 1 configured as described above will be described. FIG. 3 is a flow chart illustrating a flow of an etching process of the substrate W according to an embodiment.

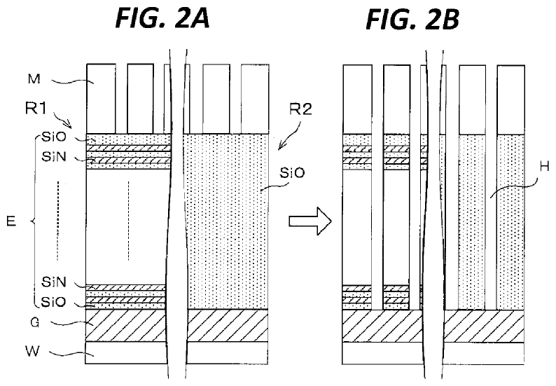

The present embodiment will be described by taking as an example a case where an etching process is performed on the substrate W in which an underlayer G (for example, SiN film), an etching target layer E, and an organic or boron-based mask layer M are stacked on a surface, as shown in FIG. 2A. In the present embodiment, the etching target layer E includes a first region R1 having a multilayer film ON in which a silicon oxide film SiO and a silicon nitride film SiN are alternately stacked, and a second region R2 having a monolayer silicon oxide film SiO. As the organic mask layer M, for example, a film including spin-on carbon, tungsten carbide, or amorphous carbon can be used. As the boron-based mask layer M, for example, a film including boron nitride or boron carbide can be used.

Further, in the present embodiment, as illustrated in FIG. 2B, a case of forming an etching hole H having a high aspect ratio in the etching target layer E through the plasma processing will be described by way of example.

In step S1, the substrate W is loaded into the plasma processing chamber 10, and the substrate W is placed on the substrate support 11. Thereafter, by supplying a DC voltage to the lower electrode of the substrate support 11, the substrate W is absorbed and held on the electrostatic chuck 114 by a Coulomb force (step S1 of FIG. 3: provision of the substrate W).

When the substrate W is held by the electrostatic chuck 114, the inside of the plasma processing chamber 10 is sealed, and the pressure inside the plasma processing chamber 10 is reduced to a desired vacuum level by the exhaust system 40. Thereafter, a sequence that includes an etching process (step S2 of FIG. 3: a first etching process) using a first processing gas described later, and an etching process (step S3 of FIG. 3: a second etching process) using a second processing gas is performed more than once. In other words, steps S2 and S3 are alternately and repeatedly performed. In these etching processes, the etching target layer E is etched, and a mask pattern (etching hole H) is formed on the substrate W as shown in FIG. 2B.

In step S2, first, a first processing gas that includes a hydrofluorocarbon gas is supplied from the gas supply 20 to the plasma processing space 10s via the shower head 13. The hydrofluorocarbon gas in step S2 is represented by CxHyFz (x represents an integer of 2 or more, y and z represent an integer of 1 or more), and includes the first hydrofluorocarbon gas having an unsaturated bond (for example, a double bond of C). Further, the first hydrofluorocarbon gas includes a fluorine substituent, for example, a trifluoromethyl group (—CF3). An example of the first hydrofluorocarbon gas is C₃H₂F₄ gas (see structural formula of FIG. 4). In step S2, the first RF generator 31a supplies the high frequency power HF for plasma generation to the upper electrode or the lower electrode and excites the processing gas to generate plasma. Further, the second RF generator 31b supplies the high frequency power LF for bias to the lower electrode, and controls the incidence of ions on the substrate W. Then, the etching target layer E (the first region R1 and the second region R2) formed on the substrate W is subjected to the etching process by the action of the generated plasma.

The first processing gas may include, in addition to the first hydrofluorocarbon gas, a second hydrofluorocarbon gas different from the first hydrofluorocarbon gas. The second hydrofluorocarbon gas may be a hydrofluorocarbon gas that does not have an unsaturated bond. Further, the second hydrofluorocarbon gas may be a hydrofluorocarbon gas having a molecular weight smaller than a molecular weight of the first hydrofluorocarbon gas. The second hydrofluorocarbon gas may be, for example, at least one selected from the group consisting of CH2F2 gas and CHF3 gas. In a case where the first processing gas includes the second hydrofluorocarbon gas, a flow ratio of the first hydrofluorocarbon gas to the second hydrofluorocarbon gas may be 0.3 or more and 0.5 or less.

Further, the first processing gas may further include at least one type of a fluorocarbon gas selected from the group consisting of C₄F₆ gas, CF₄ gas, C₄F₈ gas, and C₃F₈ gas. The first processing gas may further include at least one selected from the group consisting of CO gas, COS gas, and O₂ gas, NF₃ gas, and SF₆ gas. The first processing gas may further include an inert gas (for example, a rare gas such as Ar, or N₂ gas).

In step S2, the high frequency power LF for bias may be, for example, 20 kW or more. By setting the high frequency power LF for bias to 20 kW or more, the amount of ions reaching the bottom portion of the etching hole H having a high aspect ratio is increased, so that the etching at the bottom portion of the etching hole H can be promoted.

Further, in step S2, both the high frequency power HF for plasma generation and the high frequency power LF for bias may be periodically supplied. A period in which the high frequency power HF for plasma generation is supplied to the upper electrode or the lower electrode may be synchronized with a period in which the high frequency power LF for bias is supplied to the lower electrode. The frequency defining the cycle in which the high frequency power HF for plasma generation is supplied may be, for example, 2 kHz or more and 10 kHz or less, or 2 kHz or more and 5 kHz or less. In this case, the duty ratio indicating the ratio occupied by the time when the high frequency power HF for plasma generation is supplied to the upper electrode in one cycle may be, for example, 20% or more and 60% or less, or 30% or more and 50% or less. By controlling the frequency and the duty ratio of the high frequency power HF for plasma generation within the above-described range, the dissociation of plasma can be suppressed, and a generation amount of radicals of a polymer can be increased. As a result, the amount of the polymer as a protective film that adheres to the sidewall of the etching hole H can be increased.

The plasma generated from the first hydrofluorocarbon gas included in the first processing gas used in step S2 has a higher etching rate for the silicon nitride film SiN than an etching rate of the silicon oxide film SiO. That is, in step S2, the etching rate of the first region R1 is higher than the etching rate of the second region R2. Therefore, in step S2, the first region R1 is preferentially etched than the second region R2. Therefore, in a case where a difference between the depth of the etching hole H formed in the first region R1 and the depth of the etching hole H formed in the second region R2 is large, step S3 to be described below may be performed.

In step S3, first, the second processing gas that includes at least one type of a fluorocarbon gas selected from the group consisting of C₄F₆ gas, CF₄ gas, C₄F₈ gas, and C₃F₈ gas is supplied from the gas supply 20 to the plasma processing space 10s via the shower head 13. The second processing gas may not include the first hydrofluorocarbon gas, or may include the first hydrofluorocarbon gas at a flow ratio different from a flow ratio of the first hydrofluorocarbon gas to a total flow rate of the first processing gas. In one example, the second processing gas includes the first hydrofluorocarbon gas at a flow ratio lower than the flow ratio of the first hydrofluorocarbon gas to the total flow rate of the first processing gas. In step S3, the first RF generator 31a supplies the high frequency power HF for plasma generation to the upper electrode or the lower electrode, and excites the second processing gas to generate plasma. Further, the second RF generator 31b supplies the high frequency power LF for bias to the lower electrode to control the incidence of ions on the substrate W. Then, the etching target layer E (the first region R1 and the second region R2) formed on the substrate W is subjected to the etching process by the action of the generated plasma.

The second processing gas may include a third hydrofluorocarbon gas different from the first hydrofluorocarbon gas. The third hydrofluorocarbon gas may be the same gas as the second hydrofluorocarbon gas.

Further, the second processing gas may further include at least one selected from the group consisting of CO gas, COS gas, O₂ gas, NF₃ gas, and SF₆ gas. Further, the second processing gas may further include an inert gas (for example, a rare gas such as Ar, or N₂ gas).

In step S3, the high frequency power LF for bias may be 20 kW or more. Further, both the high frequency power HF for plasma generation and the high frequency power LF for bias may be periodically supplied, and the period when the high frequency power HF for plasma generation and the high frequency power LF for bias are supplied may be synchronized. The frequency defining the cycle in which the high frequency power HF for plasma generation is supplied may be, for example, 2 kHz or more and 10 kHz or less, or 2 kHz or more and 5 kHz or less. In this case, the duty ratio of the high frequency power HF for plasma generation may be, for example, 20% or more and 60% or less, or 30% or more and 50% or less.

The plasma generated from the fluorocarbon gas included in the second processing gas used in step S3 has a higher etching rate for the silicon oxide film SiO than an etching rate of the silicon nitride film SiN. That is, in step S3, the etching rate of the second region R2 is higher than the etching rate of the first region R1. Therefore, in step S3, the second region R2 is preferentially etched than the first region R1. Therefore, in step S2, in a case where the difference between the depth of the etching hole H formed in the first region R1 and the depth of the etching hole H formed in the second region R2 is large, the difference can be reduced by performing step S3.

In the present embodiment, the sequence including step S2 and step S3 may be alternately and repeatedly performed. Therefore, it is further suppressed that the difference occurs between the depth of the etching hole H formed in the first region R1 and the depth of the etching hole H formed in the second region R2. The ratio of the processing times of step S2 and step S3 performed in this sequence can be arbitrarily determined. In an example, from a viewpoint of appropriately forming the etching hole H in both the first region R1 and the second region R2, a ratio of the processing time of step S2 (first etching process) to the processing time of step S3 (second etching process) may be 2 or more and 3 or less.

When the formation of the mask pattern (etching hole H) on the etching target layer E of the substrate W is completed, the etching process in the plasma processing apparatus 1 is ended (step S4 in FIG. 3: stop of the etching process).

The substrate W subjected to the etching process is then unloaded from the plasma processing chamber 10 by a substrate transfer mechanism (not illustrated) (step S5 of FIG. 3: unload of the substrate W), and a series of plasma processing on the substrate W is ended.

<Operations and Effects of Technique of Present Disclosure>

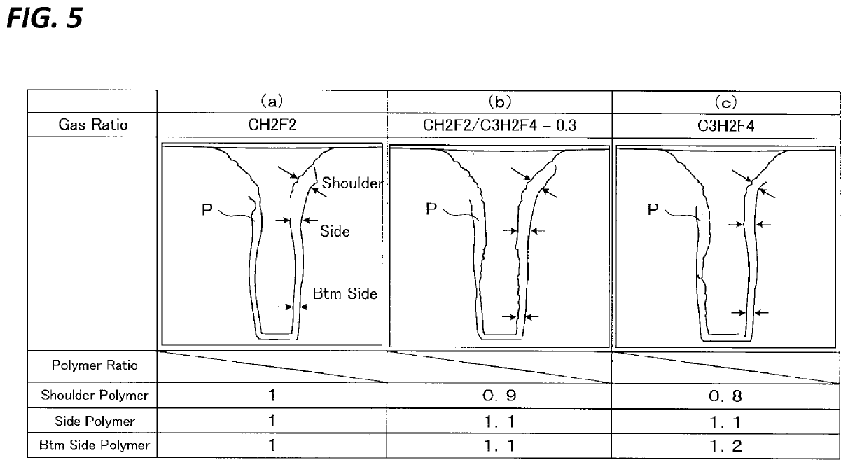

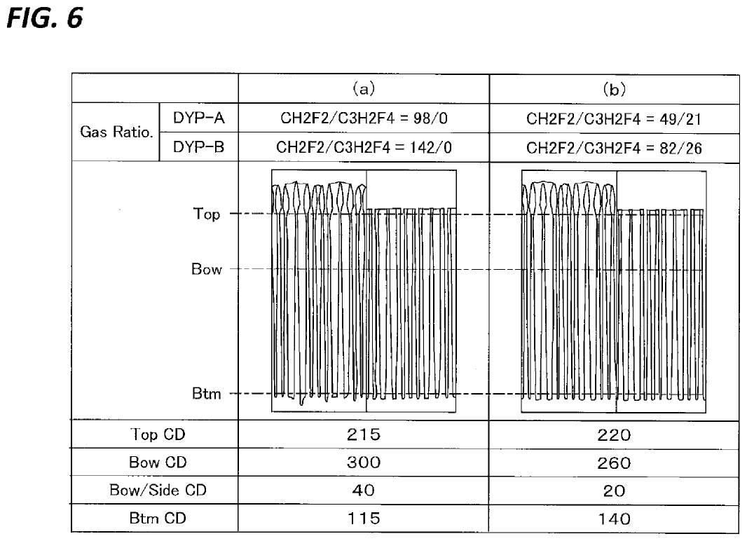

FIG. 5 is an explanatory view illustrating, as an example, a trend of an etching process result according to an example. (a) of FIG. 5 shows an amount of formation of the polymer P with respect to the sidewall of the etching hole H in a case where only CH₂F₂ gas is supplied (Reference Example 1), (b) of FIG. 5 shows the same in a case where CH₂F₂ gas and C₃H₂F₄ gas are mixed and supplied (Example 1), and (c) of FIG. 5 shows the same in a case where only C₃H₂F₄ gas is supplied (Example 2), respectively. In (b) and (c) of FIG. 5, the amount of formation of the polymer is represented by the ratio in a case where the amount of formation of the polymer in Reference Example 1 is set to be a reference value “1”. FIG. 6 is an explanatory view illustrating an example of a trend of the etching process result according to the example. (a) of FIG. 6 shows a trend of the CD value of the etching hole H in a case where only CH₂F₂ gas is supplied (Reference Example 2). (b) of FIG. 6 shows a trend of the CD value of the etching hole H in a case where CH₂F₂ gas and C₃H₂F₄ gas are mixed and supplied (Example 3).

As shown in FIG. 5, it can be seen that as the flow ratio of C₃H₂F₄ gas increases with respect to CH₂F₂ gas in the etching process, a formation position of the polymer P on the sidewall of the etching hole H changes. Specifically, it can be seen that as the flow ratio of C₃H₂F₄ gas which is supplied increases, the formation position of the polymer P transits from the upper side (shoulder) to the bottom side (Btm Side) of the etching hole H.

Further, as shown in FIG. 6, in the etching process, it can be seen that the formation of bowing with respect to the etching hole H is suppressed by supplying C₃H₂F₄ gas to the plasma processing space 10s in addition to CH₂F₂ gas. Specifically, it can be seen that the BowCD value (CD value in the middle of the etching hole H) in Example 3 is smaller than the BowCD value in Reference Example 2. Further, it can be seen that the BtmCD value (CD value at the bottom portion of the etching hole H) is larger than the BtmCD value in Reference Example 2. In other words, it can be seen that a difference between the TopCD value (CD value at the upper portion of the etching hole H), the BowCD value, and the BtmCD value becomes small, and the bowing is suppressed, so that the etching hole H having a high aspect ratio is appropriately formed.

In this way, by using C₃H₂F₄ gas as the etching gas in the etching process, the formation position of the polymer that is a reaction product transits to the bottom side of the etching hole H, and the bowing that occurs in the etching hole H can be improved. This is considered due to reactivity of C₃H₂F₄ gas being smaller than reactivity of CH₂F₂ gas. Specifically, the formation position of the polymer is transited from the upper portion side of the etching hole H to the sidewall surface that is the occurrence position of the bowing, so that the sidewall surface of the etching hole H is protected thereby suppressing occurrence of bowing. Further, since the amount of ions reaching the bottom portion of the etching hole H having the high aspect ratio increases, the etching at the bottom portion of the etching hole H is promoted.

Further, in the present embodiment, as described above, the high frequency power LF for bias is supplied to the lower electrode by, for example, a pulse wave of 20 kW or more. Accordingly, it is possible to draw ions into the etching hole H and advance the etching in the ON time of the high frequency power LF, and it is possible to uniformly and firmly generate the polymer as the protective film on the sidewall of the etching hole H without drawing ions into the etching hole H in the OFF time. In other words, the sidewall of the etching hole H in the ON time can be protected by the polymer formed in the OFF time, so that occurrence of bowing is suppressed.

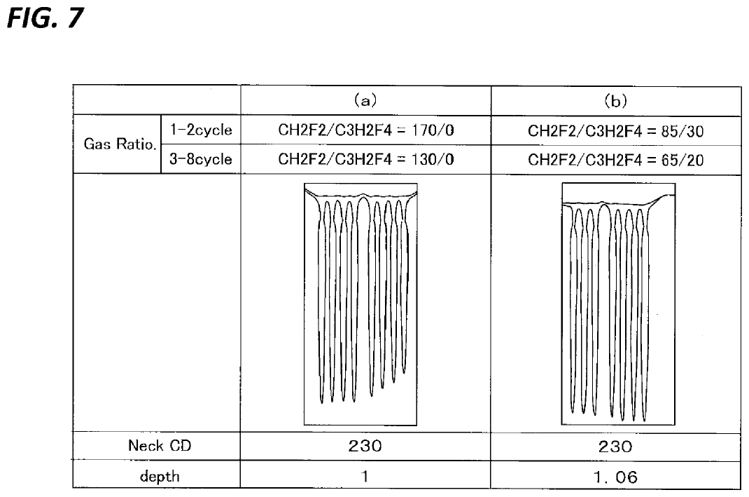

Next, FIG. 7 is an explanatory view illustrating, as an example, a trend of the etching process result according to the example. (a) of FIG. 7 shows a depth (etching rate) of the etching holes H in a case (Reference Example 3) where only CH₂F₂ gas is supplied, and (b) of FIG. 7 shows the same in a case (Example 4) where CH₂F₂ gas and C₃H₂F₄ gas are mixed and supplied, respectively. (b) of FIG. 7 shows a ratio of the depth of the etching hole H in a case where the depth of the etching hole H in Reference Example 3 is set to the reference value “1”. In Example 4, in order to appropriately compare the etching rate with that in Reference Example 3, the plasma processing is performed under the same processing conditions (processing time, processing pressure, processing temperature, and the like) as those in Reference Example 3, and the ratio of 02 gas in the processing gas was adjusted and thereby adjustment was performed such that the neck CD value was uniform.

As shown in FIG. 7, it can be seen that the forming rate, that is, the etching rate (amount of etching per hour) of the etching hole H is increased by supplying C₃H₂F₄ gas in addition to CH₂F₂ gas to the plasma processing space 10s in the etching process. Specifically, as a result of the examination by the present inventors, it can be seen that (a) the etching rate can be improved by 5% or more (6% in the illustrated example) with respect to Reference Example 3 by mixing C₃H₂F₄ gas as the etching gas with the processing gas. As described above, this is considered due to the fact that the etching at the bottom portion of the etching hole H was promoted by the increase in the amount of ions reaching the bottom portion of the etching hole H having the high aspect ratio.

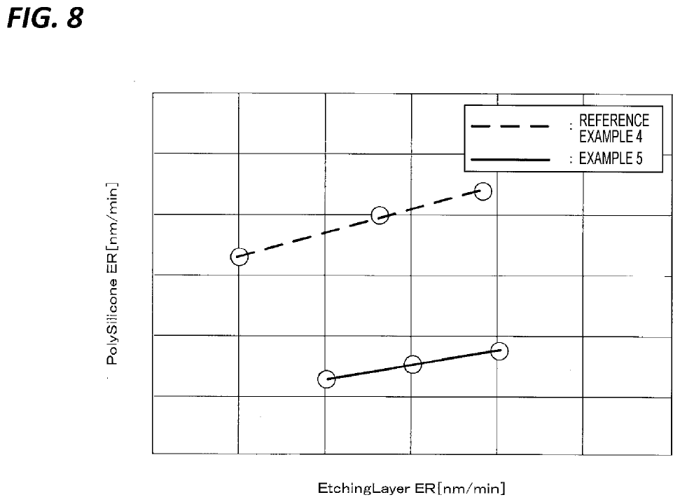

Next, FIG. 8 is a graph illustrating the etching rate (horizontal axis) of the etching target layer E and the etching rate (vertical axis) of the silicon-based chamber inner member in a case where the first processing gas that includes C₃H₂F₄ gas is used. In FIG. 8, a solid line represents the etching rate of the etching target layer E and the etching rate of the silicon-based chamber inner member in a case of using the first processing gas (Example 5), and a broken line represents the same in a case of not using the first processing gas (Reference Example 4).

During the etching process (steps S2 and S3 of FIG. 3) of the etching target layer E, the silicon-based member (for example, the shower head 13, the ring assembly 112, and the like) disposed inside the plasma processing chamber 10 is etched and consumed at the same time as the etching of the etching target layer E. Then, in a case where the silicon-based chamber inner member is consumed in this way, a plasma generation environment inside the plasma processing chamber 10 may vary, and uniform etching process results may not be obtained for the substrate W.

In this respect, in the etching process according to the present embodiment, it is possible to reduce the consumption of the silicon-based chamber inner member by performing the etching process of the substrate W using the first processing gas that includes C₃H₂F₄ gas as the first hydrofluorocarbon gas. Specifically, as shown in FIG. 8, it can be seen that it is possible to reduce the consumption (etching rate) of the silicon-based chamber inner member by about 50% while the etching rate is improved (improved by 5% or more as shown in FIG. 7) compared with Reference Example 4 by mixing C₃H₂F₄ gas as the etching gas with the processing gas. As described above, this is considered due to the fact that C₃H₂F₄ gas includes a fluorine substituent (trifluoromethyl group in the embodiment) so that the etching rate is improved and at the same time, the polymer as the protective film can be formed on the surface of the silicon-based chamber inner member by including an unsaturated bond (double bond of C in the embodiment).

Above, as can be seen from the results shown in FIGS. 5 to 7, by using C₃H₂F₄ gas as the etching gas in the etching process, occurrence of bowing on the sidewall of the etching hole H is suppressed. Further, the etching rate can be improved in the etching process.

Further, according to the present embodiment, as described above, by alternately and repeatedly performing the plasma processing (step S2) using the first processing gas that includes the first hydrofluorocarbon gas and the plasma processing (step S3) using the second processing gas that includes the fluorocarbon gas, the etching hole H can be appropriately formed in both the first region R1 and the second region R2 serving as the etching target layer E.

Further, according to the present embodiment, as can be seen from the results shown in FIG. 8, by using C₃H₂F₄ gas as the etching gas in the etching process, it is possible to reduce the consumption of the silicon-based chamber inner member while improving the etching rate.

According to the embodiment described above, in the etching process, the formation position of the polymer with respect to the etching hole H can be appropriately adjusted by using the first hydrofluorocarbon gas and the second hydrofluorocarbon gas in combination, and controlling the flow rate of each hydrofluorocarbon gas.

In the embodiment described above, as an example, a case is described where the etching target layer E includes the first region R1 having the multilayer film ON in which the silicon oxide film SiO and the silicon nitride film SiN are alternately stacked, and the second region R2 having the monolayer silicon oxide film SiO, as described above. However, the type of the etching target layer E formed on the substrate W is not limited thereto. Specifically, for example, even in a case where only the first region R1 (multilayer film ON in which the silicon oxide film SiO and the silicon nitride film SiN are alternately stacked) is formed as the etching target layer on the surface of the substrate W, the plasma processing according to the embodiment described above can be performed.

In the embodiment described above, steps S2 and S3 are alternately and repeatedly performed to control uniformly the depth of the etching hole H formed in the first region R1 and the second region R2. However, in a case where only the first region R1 is formed as the etching target layer in this way, step S3 in which the second region is preferentially etched may be appropriately omitted. In addition, in a case where only the first region R1 is formed in this way, the ratio in processing time between step S2 and step S3 may be appropriately changed such that the processing time of step S2 becomes longer than the processing time of step S3.

In the embodiment described above, a case where the etching hole H as the mask pattern is formed in the etching target layer E has been described as an example. However, the patterning shape formed in the etching target layer E is not limited to the hole shape, and may be, for example, a trench shape.

In the embodiment described above, a case where the unsaturated bond included in the first hydrofluorocarbon gas is the double bond of C and the fluorine substituent is the trifluoromethyl group (—CF3) has been described as an example. However, the structure of the first hydrofluorocarbon gas is not limited thereto. That is, for example, the unsaturated bond included in the first hydrofluorocarbon gas may be a triple bond of C, and the fluorine substituent may be any fluoromethyl group (—CFx). Further, for example, the number of unsaturated bonds or fluoromethyl groups included in the first hydrofluorocarbon gas is not limited to one.

According to the present disclosure, an etching shape having a high aspect ratio can be appropriately formed.

From the foregoing, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. An etching method comprising:
(a) providing a substrate on a substrate support inside a chamber, the substrate including a first region having a multilayer film in which a silicon oxide film and a silicon nitride film are alternately stacked and a second region having a monolayer silicon oxide film; and
(b) etching the substrate with plasma generated from a first processing gas that includes a hydrofluorocarbon gas,
wherein the hydrofluorocarbon gas includes a first hydrofluorocarbon gas represented by CxHyFz (x represents an integer of 2 or more, and y and z represent an integer of 1 or more) and having an unsaturated bond.

2. The etching method according to claim 1, wherein the first hydrofluorocarbon gas has a fluoromethyl group (—CFx).

3. The etching method according to claim 1, wherein the first hydrofluorocarbon gas is C₃H₂F₄ gas.

4. The etching method according to claim 1, wherein the first processing gas further includes a second hydrofluorocarbon gas different from the first hydrofluorocarbon gas.

5. The etching method according to claim 4, wherein the second hydrofluorocarbon gas does not have an unsaturated bond.

6. The etching method according to claim 4, wherein the second hydrofluorocarbon gas has a molecular weight smaller than a molecular weight of the first hydrofluorocarbon gas.

7. The etching method according to claim 4, wherein in (b), a flow ratio of the first hydrofluorocarbon gas to the second hydrofluorocarbon gas is 0.3 or more and 0.5 or less.

8. The etching method according to claim 4, wherein the second hydrofluorocarbon gas is at least one selected from the group consisting of CH₂F₂ gas and CHF₃ gas.

9. The etching method according to claim 1, further comprising: (c) etching the substrate with plasma generated from a second processing gas that includes a fluorocarbon gas.

10. The etching method according to claim 9, wherein the second processing gas does not include the first hydrofluorocarbon gas or includes the first hydrofluorocarbon gas at a flow ratio different from a flow ratio of the first hydrofluorocarbon gas to a total flow rate of the first processing gas.

11. The etching method according to claim 9, wherein the second processing gas includes a third hydrofluorocarbon gas different from the first hydrofluorocarbon gas.

12. The etching method according to claim 11, wherein the third hydrofluorocarbon gas does not have an unsaturated bond and has a molecular weight smaller than a molecular weight of the first hydrofluorocarbon gas.

13. The etching method according to claim 9, wherein (b) and (c) are alternately repeated.

14. The etching method according to claim 13, wherein a ratio of the processing time in (b) to the processing time in (c) is 2 or more and 3 or less.

15. The etching method according to claim 1, wherein the first processing gas further includes a fluorocarbon gas.

16. The etching method according to claim 9, wherein the fluorocarbon gas is at least one selected from the group consisting of C₄F₆ gas, CF₄ gas, C₄F₈ gas, and C₃F₈ gas.

17. The etching method according to claim 1, the first processing gas further includes at least one selected from the group consisting of CO gas, COS gas, O₂ gas, NF₃ gas, and SF₆ gas.

18. The etching method according to claim 1, wherein in (b), high frequency power for bias of 20 kW or more is supplied to the substrate support.

19. The etching method according to claim 1, wherein a surface of the substrate has an organic or boron-based mask.

20. An etching processing apparatus comprising:
a processing chamber;
a substrate support provided inside the processing chamber to hold a substrate; and
a controller for controlling an etching process applied to the substrate,
wherein the controller performs a process including
(a) providing the substrate on the substrate support inside a chamber, the substrate including a first region having a multilayer film in which a silicon oxide film and a silicon nitride film are alternately stacked and a second region having a monolayer silicon oxide film, and
(b) etching the substrate with plasma generated from a first processing gas that includes a hydrofluorocarbon gas, and
the controller controls the etching process such that the hydrofluorocarbon gas includes a first hydrofluorocarbon gas represented by CxHyFz (x represents an integer of 2 or more, and y and z represent an integer of 1 or more) and having an unsaturated bond.
